(19) United States
(12) Patent Application Publication
(10) Pub. No.: US 2006/0238971 A1
(43) Pub. Date: Oct. 26, 2006

(54) Electronic device docking station and method of use

(76) Inventor: Jeff Compton, Austin, TX (US)

Correspondence Address: NAMAN, HOWELL, SMITH & LEE, P.O. BOX 1470, WACO, TX, 76703, US

(21) Appl. No.: 11/110,523

(22) Filed: Apr. 20, 2005

(51) Int. Cl. G06F 1/16; H05K 5/00; H05K 7/00

(52) U.S. Cl. 361/686

(57) ABSTRACT

An improved docking station for electronic devices and an associated method of use. The docking station is characterized by a docking module that may be partially inset within, or secured to, the sun visor of a vehicle. The docking module is configured to securely hold a portable electronic device therein, which may be removed by its user. The docking module further provides for a plug, which in combination with electric, audio, and communication wiring, allows for communication between the portable electronic device and other peripheral devices located within the vehicle. In addition, the wiring may also be run with the vehicle sun visor.

### BACKGROUND OF THE INVENTION

1. Field of the Invention

The present invention generally relates to an improved docking station for electronic devices and an associated method of use. More specifically, the present invention relates to an improved docking station for electronic devices and method of use where the docking station provides for electronic devices to be secured and powered by components within a vehicle.

2. Background Information

The use of electronic device docking units and are known in the art. More specifically, electronic device docking units heretofore devised and utilized are known to consist basically of familiar, expected and obvious structural configurations, notwithstanding the myriad of designs encompassed by the crowded prior art, which have been developed for the fulfillment of countless objectives and requirements. While these other docking units may fulfill their respective, particularly claimed objectives and requirements, the aforementioned apparatus do not disclose an electronic device docking unit and method of use such as Applicant's present invention.

Electronic device docking units and power converters are known in the art to be installed on the center console or dashboard of a vehicle. Such installation may be desirable in so much as the docking unit will be within close proximity for use by the driver. With a center console or dashboard mounted docking station, the driver or front seat passenger will easily be able to change media devices (i.e. from the CD player to the radio) or stations on the electronic device. Center mounted docking stations also allow for the driver to be close to the power converter. The driver or the passenger can simply unplug the converter to switch power sources or to cease the operation of the item. Moreover, the location of the docking device on the console or dashboard follows the established tradition of where the radio, tape player, or CD player should be located. This center mount has followed the tradition of electronic devices within vehicles; however, this location does not offer the best location for modern technology and media devices in all instances.

There are several situations where mounting an electronic device on the center console or dashboard is undesirable. For instance, a center console or dashboard location tends to create unnecessary clutter about the instrument panel. As modern vehicles have become more sophisticated, the driver or passengers may have any number of different gauges and/or displays conveying information simultaneously. The addition of an electronic device about the instrument or display area (i.e., the dashboard) brings about confusion and further consumes valuable dashboard and console space that might be used for more necessary purposes.

A center mount docking station takes space from the center console, and the cords associated with the docking station provide an entirely new problem. A typical docking station will have at least two separate cords. The first cord will attach the device to the cigarette lighter as a power cord. The second cord will attach the electronic device to the vehicle's main stereo system. This configuration typically necessitates the use of a tape deck converter or the use of an FM modulator. In any event, such a configuration will result in unruly wiring that must strewn about the interior of the car. This clutter and messy appearance within the vehicles leaves much to be desired in terms of efficiency. As such, there is a great need for a new way to keep the original lines of the car and find a new location to mount electronic devices.

Outside of the poor aesthetics offered by a center mounted docking station and power converter, a dashboard or center console docking station leaves the electronic device in the open for any passerby to see. One must only once be the victim of a stolen stereo, cellular telephone, or laptop computer to understand the need to keep the expensive technology device out of the common sight of a potential thief. To protect the media device, the vehicle's driver must dismantle the media device by removing the center mounted docking station, or by removing a crucial component to the media device like the faceplate of the radio. To remedy this problem, a vehicle owner needs a safe and secure location for a media device that will protect the technology from a potential thief.

Modern improvements in car electronic devices have also led to the increased need for new locations to mount the technology in the car. Individuals are no longer happy with just one or two pieces of technology in the car. It is not uncommon to see a vehicle that having a multimedia configuration, comprising a cellular telephone, electronic device, laptop computer mount, and a notepad all within the confines of the center console. Coupled with the storage of the center console and the cup holders usually found in the center console, the need for a new mount and location is readily seen. Individuals want and desire different places to put their technology where the car will retain the clean lines of its original design. Applicant's invention strives to create a docking station in a location where the electronic device will be protected from the elements, thieves, and the overwhelming clutter of technology that can impede the driver and create an overall feeling of messiness within the car.

Devices known in the art fail to provide a mechanism whereby an electronic device may be secured about the sun-visor of a typical vehicle. Instead, known docking devices and power converters focus on the center console or dashboard of the car. This docking location offers the closest proximity to the power converter, but these docking devices forfeit the ability to have the media device out of the way of the driver, and in a secure place between the sun-visor and the roof of the car. The known docking stations allow for docking in or around the common controls for the radio, and a certain number of docking stations actually place the media device in one of the vehicle's cup holders. However, none of these locations or docking stations offers the benefits associated with Applicant's present invention.

### SUMMARY OF THE INVENTION

The general purpose of the present invention, which will be described subsequently in greater detail, is to provide an improved docking station for electronic devices and method of use where the docking station provides for electronic devices to be secured and powered by components within a vehicle; specifically, where the electronic device may be secured about a vehicle's sun-visor. Applicant's invention contains many of the advantages of such devices and methods known in the art and many novel features that result in a new docking device and method of use which is not anticipated, rendered obvious, suggested, or even implied by any of the known apparatus or methods, either alone or in any combination thereof.

In satisfaction of the above, the present invention provides an improved docking station and method of use for mobile electronic devices in a vehicle. The present invention, by way of a novel combination of components and a particularly effective method of using that combination, yields results that simply are not possible with any other known docking units. The audio docking device apparatus will utilize the pivot arm in a normal vehicle sun-visor to keep wiring free from other locations. Rather than allowing the wires to congregate and clutter the center console of the vehicle, the pivot arm offers a clean location with a space to allow running of the wires to the power converter and docking station. The pivot arm also offers a secure anchor location for all of the wiring and wire harnesses associated with installing electronic devices within a vehicle.

By placing the electronic docking device on the sun-visor, the docking device will also keep all of the technology and components of the technology within an enclosed area. The driver will not have to fumble around several different locations in the car to find each of the components. Rather, all parts of the media device, and potentially all of the control of the media device, will be within the sun-visor. This novel approach to the use of the docking station on the sun-visor avoids all of the clutter problems associated with mounting a media device in the center console of the automobile by moving the device off of the center console and by having a secure and clean location to anchor all of the wires associated with the device.

Applicant's invention further secures the electronic device by keeping the technology out of the line of sight. The media device will be located on the sun-visor. To secure the device, the driver must only flip up the sun visor. The media device does not have to be removed from the car or dismantled from the center console. Rather, by flipping up the sun visor, the driver can take the media device out of sight and place the media device in a secure location—a location away from the eyesight of thieves who might search the car for different objects to steal.

Known vehicle mounts for electronic devices focus on keeping the mount in the center console close to the radio controls and the power outlets. With modern technological advancements, drivers experience a plethora of different items on the dashboard and console of the vehicle. Applicant's invention, by placing the docking unit and power converter on the sun-visor of the vehicle, frees this space, allows for clean installation of all wires, and keeps the unit out of the line of sight of potential thieves. Applicant's invention remedies each of the problems associated with the known vehicle media mounts.

### BRIEF DESCRIPTION OF THE DRAWINGS

Applicant's invention may be further understood from a description of the accompanying drawings, wherein unless otherwise specified, like referenced numerals are intended to depict like components in the various views.

FIG. 1 is a schematic view of the preferred embodiment of the present invention.

FIG. 2 is another schematic view of the preferred embodiment of the present invention.

### DETAILED DESCRIPTION OF THE PREFERRED EMBODIMENT

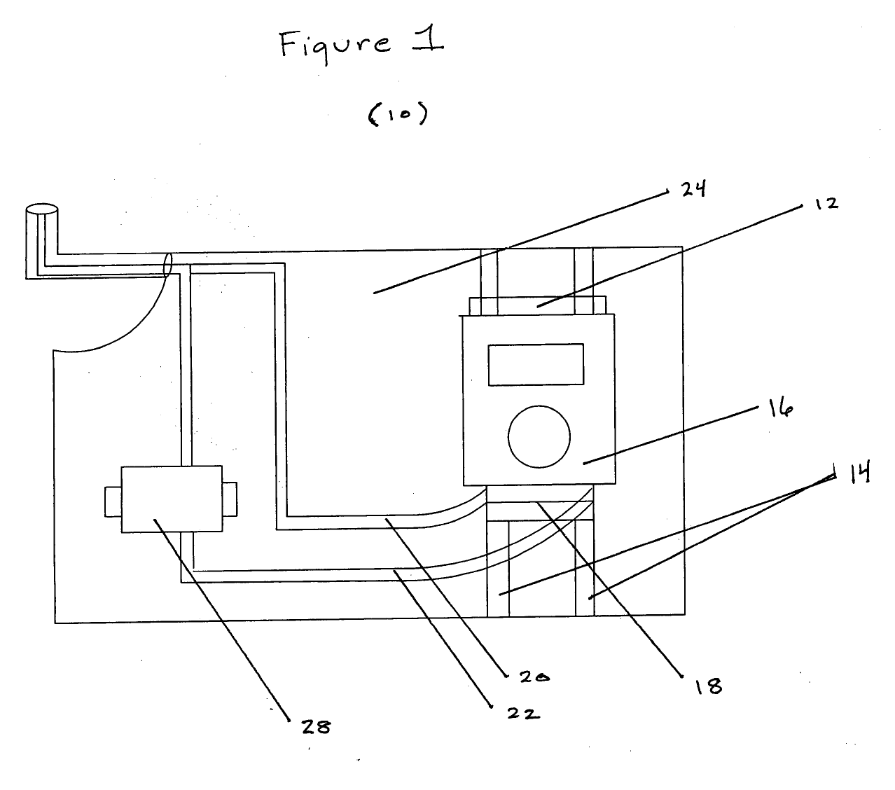

Referring to FIG. 1, the preferred embodiment of the present invention is generally designated by reference numeral 10. In the preferred embodiment, device 10 is characterized by a docking module 12. In one embodiment, docking module 12 is actually inset within sun visor 24. Alternative embodiments are envisioned where docking module 12 is secured to sun visor 24 by some securing means 14. Securing means 14 may take on several forms such as a series of straps extending around sun visor 24, or perhaps a plastic mold fit to surround sun visor 24. Preferably, docking station is secured to sun visor 24 as it remains partially inset therein and is attached to securing means 14.

Electronic device 16 remains securely engaged with docking module 12 so that device 16 may be forcibly removed or inset within docking station 12. Such a configuration may be achieved as docking module 12 may be of a particular dimension to securely surround device 16. Alternative embodiments are envisioned where docking module 12 may be comprised of malleable material that is able to fit to the form of device 16. And, yet other embodiments are envisioned where the dimensions of docking module 12 are mechanically adjustable by rotation of some fastening means such as a screw or pin and dow combination. In each embodiment, however, device 16 may be removed from docking module 12 in an efficient manner.

Plug 18 receives media communication means 20 and 22 and engages device 16 so that media information may be effectively communicated between device 16 and other system compoonents via medial communication means 20 and 22. In the preferred embodiment, media communication means 20 and 22 are singular or bundled wires capable of handling low to mid level voltage moderate current there through. In the preferred embodiment, media communication means extend from device 16 (via plug 18) to visor pin within sun visor 24. Communication means 20 and 22 are simply inset within the material of sun visor 24 so that they remain unexposed to the surrounding environment. Of course, this provides for efficiency in use and an attractive appearance.

Referring again to FIG. 1, particular embodiments are also envisioned where AC/DC converter 28 is also contained and surrounded by sun visor 24.

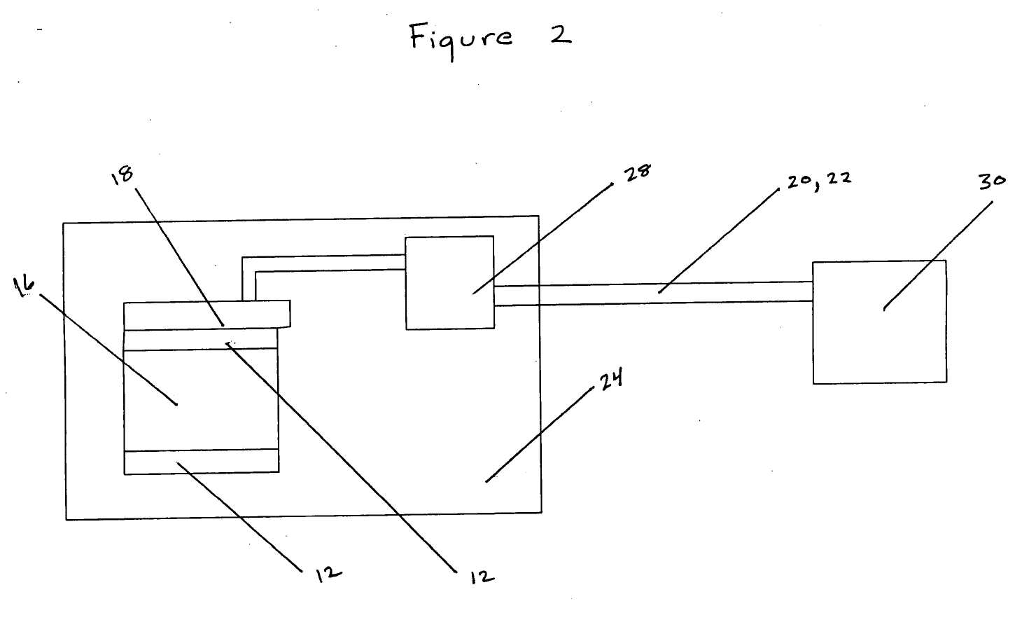

FIG. 2 provides a block diagram, which traces the preferred embodiment of the power supply and audio connection. Power source 30 represents the vehicle's power source. Power source 30 will connect to converter 28 through media communication means 20 and 22. Media communication means 20 and 22 connect converter 28 which will be located within the confines provided by sun visor 24. After the power supply travels through power converter 28, power will be supplied via communication means 20 and 22 as to carry the appropriate power through plug 18, which has been sandwiched with device 16. Finally, the appropriate level of power provided by power source 30 will enter media device 16. The audio frequencies provided by media device 16 may flow the opposite direction through the adjacent media communication means. Media device 16 will produce the audio frequencies that will then be transferred through input component 18, which is housed by docking apparatus 12. Traveling through media communication means 22, the audio supply will connect to vehicle audio device (not pictured), which will provide the audio over the vehicle's stereo system.

Although the invention has been described with reference to specific embodiments, this description is not meant to be construed in a limited sense. Various modifications of the disclosed embodiments, as well as alternative embodiments of the inventions will become apparent to persons skilled in the art upon reference to the description of the invention. It is, therefore, contemplated that the appended claims will cover such modifications that fall within the scope of the invention.

I claim:

1. An improved docking apparatus comprising
a docking module partially set within a vehicle sun visor and configured to secure a portable electronic device therein;
a media communication means configured for transmitting audio, electronic, and media information to and from said portable electronic device, where said media communication means is at least partially concealed within said sun visor;

2. The apparatus of claim 1 further comprising
said sun visor configured for partially receiving said docking module and further configured for at least partially concealing said communication means.

3. The apparatus of claim 1 further comprising
an AC /DC converter configured for converting a power signal from a first mode to a second mode, or from a second mode to a second mode, in combination with said communication means.

4. An improved docking apparatus comprising
a docking module secured to a vehicle sun visor a securing means and configured to secure a portable electronic device therein;
a media communication means configured for transmitting audio, electronic, and media information to and from said portable electronic device, where said media communication means is at least partially concealed within said sun visor.

5. The apparatus of claim 4 further comprising
said sun visor configured for partially receiving said docking module and further configured for at least partially concealing said communication means.

6. The apparatus of claim 4 further comprising
an AC /DC converter configured for converting a power signal from a first mode to a second mode, or from a second mode to a second mode, in combination with said communication means.
